(19) United States
(12) Patent Application Publication
(10) Pub. No.: US 2024/0076900 A1
(43) Pub. Date: Mar. 7, 2024

(54) DEVICES, METHODS AND SYSTEMS FOR MONITORING ELECTRIC FENCES

(71) Applicant: Gallagher Group Limited, Hamilton (NZ)

(72) Inventor: Kerry Ian Bodman, Hamilton (NZ)

(73) Assignee: Gallagher Group Limited, Hamilton (NZ)

(21) Appl. No.: 18/272,327

(22) PCT Filed: Jan. 13, 2022
(86) PCT No.: PCT/NZ2022/050003

§ 371 Date: Jul. 13, 2023

(30) Foreign Application Priority Data
Jan. 13, 2021 (NZ) 771830

(51) Int. Cl. E04H 17/00; H05C 1/04

(52) U.S. Cl. CPC E04H 17/017; H05C 1/04

(57) ABSTRACT

Systems and methods for monitoring a fence system are disclosed. At least one power impulse is provided to the fence system, and at least one parameter of the power impulse on the fence system is measured a predetermined delay time after the impulse was supplied to the fence system. The measurement of the parameter continues for a predetermined duration after the predetermined delay time has expired, and one or more alarms are generated if the measured parameter falls outside of at least one threshold.

### 1. STATEMENT OF CORRESPONDING APPLICATIONS

This application is based on the provisional specification filed in relation to New Zealand Patent Application No. 771830, the entire contents of which are incorporated herein by reference.

### 2. TECHNICAL FIELD

The present technology relates to devices, methods and systems for monitoring electric fences. The technology may find particular application in monitoring electric fences in security applications. However, this should not be seen as limiting on the technology.

### 3. BACKGROUND

Security electric fence systems typically include one or more fence sections, each of which have a plurality of conductive fence wires. Periodic voltage impulses are provided to one or more of the fence wires by an electric impulse generating device known as an energiser.

In high-security applications, it is desirable for all of the wires of the fence to be provided with periodic voltage impulses by the energiser. Energising all of the fence wires improves the reliability of the fence system, provides additional resistance against attacks (such as the cutting of wires) and provides a greater deterrent to an individual attempting to get past the fence.

In some applications high-security fence systems use two or more periodic voltage impulse generating circuits, each circuit being connected to alternating fence wires. This approach provides improved protection against a wire being cut or short-circuited to ground, as the wires connected to the other voltage impulse generating circuit will remain active and able to deliver a deterrent shock to the intruder. Various detection systems and methods can be used to detect cut or shorted wires and alert a guard or security monitoring company accordingly.

Another advantage of using two or more periodic voltage generating circuits is the ability to provide voltage impulses of opposite polarity to each adjacent wire to increase the deterrent effect. By synchronising the transmission of the opposite polarity impulses, it is possible to achieve twice the voltage between the adjacent wires than would otherwise be present between each of the wires and a ground reference point.

One method of detecting shorts or cuts in a fence system is to use a sensing circuit configured to measure the voltage at one end of the fence system (typically the end electrically furthest from the energiser). This allows for rapid detection of voltage fluctuations caused by cut wires, short circuiting wires, or other forms of fence loading such as an individual attempting to climb the fence. These sensing circuits typically measure the positive or negative peak value of the voltage arriving at the sensing circuit in order to determine whether an undesirable condition is present on the fence and to generate alarms or alerts accordingly.

Existing sensing circuits can be prone to falsely detecting undesirable conditions (false positives) or failing to detect undesirable conditions (false negatives). Both failure modes are highly undesirable in any security system. Additionally, cross-coupling between adjacent fence wires can affect the accuracy of traditional sensing circuits.

It is an object of the present invention to address one or more of the foregoing problems or at least to provide the public with a useful choice.

Further aspects and advantages of the present invention will become apparent from the ensuing description which is given by way of example only.

### 4. SUMMARY

According to one aspect of the technology, there are provided devices, methods and systems for monitoring electric fences.

According to another aspect of the technology, there are provided devices, methods and systems for monitoring the voltage of an impulse applied to an electric fence.

According to another aspect of the technology, there is a provided a system for monitoring an electric fence, the system comprising:
an electric fence energiser, comprising:
   a power source;
   a power pulse generating circuit; and
   a power pulse triggering circuit adapted to provide a trigger signal to the power pulse generating circuit, and
a detector, comprising detection circuitry configured to measure at least one parameter of a power pulse,
wherein, in use the electric fence energiser is electrically connected to a first end of the electric fence, and the detector is electrically connected to a second end of the electric fence, and
wherein, the power pulse generating circuit is configured to transmit a power pulse to the electric fence upon receiving the trigger signal, and the detector is configured to measure the at least one parameter of the power pulse at a predetermined delay time after the trigger pulse is provided to the power pulse generating circuit.

In a further aspect of the technology there is provided an electric fence system, comprising:
two or more electric fence zones, wherein each electric fence zone includes a first and a second electric fence line, the first electric fence line being adjacent to and spaced apart from the second electric fence line;
an electric fence energiser electrically connected to a first end of the first electric fence line and a first end of the second electric fence line; and
a detector electrically connected to a second end of the first electric fence line and a second end of the second electric fence line,
wherein in use, the electric fence energiser supplies the first electric fence line with an electric pulse beginning with a positive polarity and the second electric fence line with an electric pulse beginning with a negative polarity, and
wherein the detector is configured to monitor one or more parameter of the electric pulse on the first electric fence line and/or one or more parameter of the electric pulse on the second electric fence line, and generate an alarm when the one or more parameters fall outside of one or more thresholds, the one or more thresholds being based at least partially upon measured parameters of the other fence zones over time.

In a further aspect of the technology there is provided an electric fence system, comprising a plurality of conductive wires the conductive wires being adjacent to one another but galvanically isolated from one another,
wherein, in use a first conductive wire is supplied with a power pulse beginning with a positive polarity, and a second conductive wire is supply with a power pulse beginning with a negative polarity, wherein the respective power pulses are supplied at substantially the same time, and
wherein a detector is configured to measure one or more parameter of the power pulses after a predetermined delay period from the time the power pulses are supplied to the respective conductive wires, and the detector is further configured to measure the one or more parameter for a predetermined duration of time.

In a further aspect of the technology there is provided an electric fence energiser comprising:
at least one power pulse generating circuit, configured to provide power pulses to one or more conductive wires; and
a power pulse triggering circuit adapted to provide a trigger signal to the at least one power pulse generating circuit,
wherein the pulse generating circuit is configured to provide the power pulses to the one or more conductive wires on receipt of the trigger signal, and
wherein the electric fence energiser is configured to communicate timing information of the power pulse triggering circuit to a detector configured to measure at least one parameter of the power pulse at a predetermined time after receipt of the trigger signal.

In a further aspect of the technology there is provided a detector configured to measure at least one parameter of a power impulse, the detector comprising,
a detection circuit configured to measure at least the voltage, current or electromagnetic field of the power impulse,
a communications interface, configured to receive timing information relating to the power impulse, the timing information including the time at which the power impulse was generated,
wherein, in use the detector is configured to measure the at least one parameter of the power impulse after a predetermined delay after the power impulse was generated, and the detector is further configured to measure the at least one parameter of the power impulse for a predetermined duration.

In a further aspect of the technology, there is provided a method of monitoring a fence system, the method comprising the steps of:
supplying at least one power impulse to the fence system;
measuring at least one parameter of the power impulse on the fence system, a predetermined delay time after the impulse was supplied to the fence system;
continuing to measure the at least one parameter of the power impulse for a predetermined duration after the predetermined delay time has expired; and
generating one or more alarms if the measured parameter falls outside of at least one threshold.

In a further aspect of the technology, there is provided a method of monitoring a fence system, the method comprising the steps of:
supplying at least one power impulse to the fence system;
measuring at least one parameter of the power impulse on the fence system, a predetermined delay time after the impulse was supplied to the fence system;
continuing to measure the at least one parameter of the power impulse for a predetermined duration before and after the predetermined delay time; and
generating one or more alarms if the measured parameter falls outside of at least one threshold.

The foregoing discussion refers to power pulses as “beginning with” a positive or negative polarity, this should be understood to mean that the voltage of the pulse waveform starts with a positive or negative transition with respect to ground. In other words, the pulse waveform may increase from substantially zero to a positive or negative voltage. It should be appreciated that this pulse waveform may oscillate or otherwise alternate between positive and negative voltages although this is not always the case, the presence and nature of oscillations may be due to a number of factors including the characteristics of the pulse generating circuit and the characteristics of the fence line, including transmission line effects as should be known to those skilled in the art.

In examples, the energiser includes a power source. The power source may be an alternating or direct current source such as line or utility power, a battery or solar power source.

In examples, the power pulse generating circuit may comprise at least one capacitive energy storage element and at least one inductive element. For example, the power pulse generating circuit may be configured to provide power pulses by discharging a capacitor through a transformer.

In examples, the power pulse triggering circuit may be configured to provide power pulses at a regular interval. For example, the interval may be between 1 and 3 seconds.

In further examples, the power pulse triggering circuit may be configured to synchronise the generation of power pulses with the generation of power pulses on neighbouring sections of fence or generated by other energiser units.

In preferred examples, the detector may be provided within the energiser unit, for example the detection circuit(s) may be positioned on a printed circuit board within the energiser unit. In alternative examples of the technology, the detector may be a standalone device which is positioned remotely from the energiser unit.

In examples, the detection circuit(s) may include at least one or more of: a peak-hold circuit, a digital signal processor, a microcontroller, and filtering or averaging circuit. In examples, the detection circuit(s) may be configured to perform wave shape analysis. In examples, the detection circuit(s) may be realised using analogue, digital, or a combination thereof, components.

In examples, the at least one parameter may comprise any one or more of voltage, current or electromagnetic field.

In examples, the detector may be configured to repeatedly or continuously measure the at least one parameter of the power pulse for a predetermined duration after the predetermined delay time. For example the detector may periodically measure the at least one parameter every 1 microsecond.

In examples, the predetermined delay time may be based on the propagation time of a power pulse on the fence. For example, the predetermined delay time may be based on both the propagation time, and the expected rise time of the power pulse waveform. For example, the predetermined delay time may be between 10 microseconds and 100 microseconds.

In examples, the predetermined delay time may be calibrated during installation of the fence system.

In examples, the predetermined delay time may be adjusted over time. For example, the predetermined delay time may be adjusted if the length of the fence is changed, or if environmental changes affect the propagation speed of the power pulse.

In examples, the predetermined delay time may be calculated by measuring the delay time between generating a power pulse and receiving a power pulse at the detector. For example, the delay time may be calculated by algorithms such as machine learning algorithms. For example a machine learning algorithm may be configured to sample both the outgoing pulse and the return pulse to determine the time delay between the outgoing pulse and the return pulse taking into account both the effects of the topology of the fence and also the environmental effects on the return pulse.

In examples, the predetermined duration may be based on the expected width of the power pulse. For example, the predetermined duration may be set such that it is less than the expected width of the power pulse. For example, the predetermined duration may be between 5 microseconds and 15 microseconds. In examples, the predetermined duration before and after the predetermined delay time may be substantially 5 microseconds—i.e. a total window of substantially 10 microseconds.

In examples, the predetermined duration may be calibrated during installation of the fence system.

In examples, the predetermined duration may be adjusted over time. For example, the predetermined duration may be adjusted if environmental changes affect the shape of the power pulse.

In examples, the predetermined duration may be decided by comparing the shape of the generated pulse to the shape of the returning pulse at the detector. For example, the predetermined duration may be set by an algorithm such as an equation or machine learning algorithm.

In examples, the electric fence energiser may be configured to measure at least one parameter of the power pulse. For example, the energiser may be configured to measure the peak voltage, current or electromagnetic field strength of the power pulse at the time of generating the power pulse.

In examples, the at least one parameter measured by the energiser may be compared with the at least one parameter measured by the detector. For example, if the voltage measured by the detector is less than a threshold percentage of the voltage measured by the detector an alarm may be generated. For example, the threshold percentage may be 50%. In examples, the threshold may be an absolute value (for example, 2000 volts).

In examples, the thresholds may be configured during installation. In other examples, the thresholds may be configured to be adjusted over time. For example, the detector may be configured to sample a plurality of fence zones and use algorithms to determine whether variations between the plurality of zones are likely to be caused by environmental effects or intruder events. In examples the algorithms may include machine learning algorithms.

In examples, the system may include one or more sensors configured to provide environmental data such as temperature, humidity, soil characteristics (for example, conductivity), salinity, solar radiation, wind characteristics (for example, direction and/or velocity), light, and/or weather characteristics (for example, rain and/or snow). As a further example, the security system may receive data from external services, for example a weather reporting service. As a further example, the data may relate to the time of day.

Other security sensors could be used to provide greater confidence of a security event as opposed to false alarms due to environmental factors. By way of example, such security sensors may include:
Tension or motion sensors to detect movement of the fence wire;
Sensors such as cameras, infra-red, microwave or radar to detect movement near the fence;
Sensors such as an accelerometer attached to the fence structure to detect movement of the fence structure; and
Fibre or coaxial cables attached to the fence to detect movement of the fence. These could also be buried under ground to detect movement near the fence.

In examples, one or more machine learning algorithms may be used to analyse the at least one parameter of the power pulse in combination with data from the one or more sensors to determine a relationship therebetween. By machine learning the relationship between environmental effects on the power pulse voltage or waveform shape the system can assign a probability to the cause of a change in the power pulse voltage or waveform, for example external environmental factors, or the result of an intruder attack on the fence. The machine learned probability assigned to the cause of the change in voltage or waveform shape can be used for determining whether to report the change as an intruder event that needs to be further investigated or an environmental related event that does not need to be further investigated and would otherwise be reported as a false alarm event. In doing so, the likelihood of false alarms may be reduced, and/or sensitivity to genuine alarms or intruder events increased.

In examples, the detector may be configured to monitor a polarity of the power pulse and generate an alarm if the polarity differs from an expected polarity. For example, the detector may be configured to detect power pulses having substantially one polarity, and upon receiving a pulse of a different polarity, the detector may be configured to generate an alarm. In an alternative example, the detector may check for a specific sequence of pulse polarities and generate an alarm when the measured polarities do not match the expected sequence. In a yet further example, the detector may compare the polarity of the power pulse to at least one parameter of the power pulse measured by the energiser, such as the power pulse polarity, current or magnetic field. The detector may be configured to generate an alarm if the polarity measured does not match the expected polarity from the energiser.

In examples, the alarm may be issued at the detector and/or the energiser, and/or may include a signal transmitted to another location—for example a monitoring station or an alarm device. In examples the alarm signal may result in one or more of: an electronic message being issued to relevant personnel, a digital alert (for example, a software flag or icon within a user interface), or activation of an audible/visible device(s).

### 5. BRIEF DESCRIPTION OF THE DRAWINGS

Further aspects of the present technology will become apparent from the ensuing description which is given by way of example only and with reference to the accompanying drawings in which:

FIG. 1 shows a block diagram of an electric fence system in accordance with the present technology;

FIG. 2 shows exemplary power pulse waveforms in accordance with the present technology; and

FIG. 3 shows exemplary power pulse waveforms in the event of a cut fence wire in accordance with the present technology.

### 6. DETAILED DESCRIPTION

### 6.1. Fence System Overview

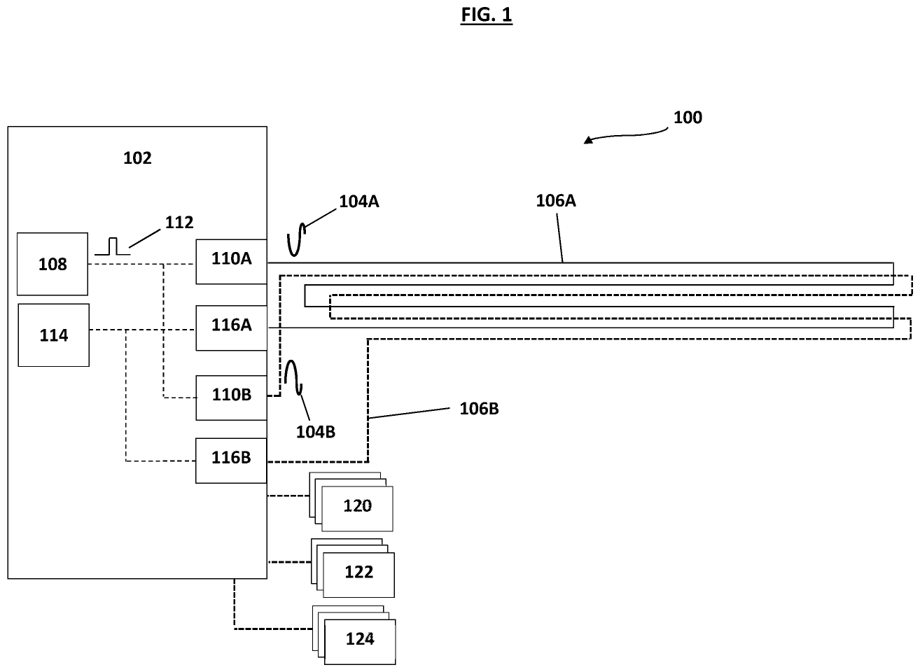

FIG. 1 is a block diagram showing the components of an electric fence system 100 according to the present technology. As illustrated, the system comprises an energiser 102 which is configured to generate periodic electrical power pulses 104A, 104B and supply the power pulses 104A, 104B to one or more conductive fence wires 106A, 106B.

The energiser 102 comprises a pulse timing circuit 108, which is operatively connected to one or more pulse generating circuits 110A, 110B. In use the pulse timing circuit 108 generates a trigger signal 112 which is used to activate the pulse generating circuits 110A, 110B and thereby provide a power pulse 104A, 104B to a first end or adjacent to a first end of each of the fence wires 106A, 106B.

For sake of simplicity the illustrated example includes two pulse generating circuits 110A, 110B, however this should not be seen as limiting on the technology and in other examples the energiser 102 may include additional pulse generating circuits, such as where a single energiser 102 provides power to multiple fence zones.

In the example shown the first pulse generating circuit 110A is configured to generate a power pulse 104A which has a predominantly negative waveform, that is to say that the greatest percentage of energy delivery occurs when the voltage of the power pulse 104A is negative with respect to a ground reference or alternatively that the power pulse 104A begins with a negative waveform. For sake of simplicity the foregoing discussion refers to this waveform simply as a negative power pulse, and the converse signal a positive power pulse. In contrast the second pulse generating circuit 110B is configured to generate a positive power pulse 104B.

The pulse timing circuit 108 ensures that both pulse generating circuits 110A, 110B are triggered substantially simultaneously with one another. However, in other examples of the technology it may instead be advantageous to offset the pulse generating circuits 110A, 110B, for example where a single polarity of power pulse 104A, 104B is generated or where less voltage between adjacent wires is required.

It is common practice to alternate the fence wires 106A and 106B along each fence section, so that each adjacent wire has an opposite polarity power pulse 104A, 104B. This approach advantageously provides twice the voltage between neighbouring wires 106A, 106B than would otherwise be present between each wire 106A, 106B and a ground reference. This increase in voltage can be beneficial in delivering a deterrent shock to anyone who makes contact with both wires 106A, 106B.

The fence wires 106A, 106B are also commonly placed in close proximity with one another. For example, between 60 mm and 90 mm from one another. However, this should not be seen as limiting on the technology and in practice the spacing may be set at any desired distance.

The distal or second end of each of the fence wires 106A, 106B is operatively connected to a detector 114 which includes one or more detection circuit 116A, 116B. In use the detection circuits are used to measure one or more parameter of the inbound power pulse 104A, 104B waveform. For example the parameter may include one or more of waveform voltage, current, electromagnetic field, frequency, duration, number of oscillations or any other parameter associated with the power pulses 104A, 104B.

It should be appreciated that, depending on the length of the fence wire 106A, 106B the power pulse 104A, 104B arriving at the detection circuit 116A, 116B will be delayed from the time of the pulse delivered to the first end of the electric fence wire by a time which depends on the propagation velocity of the power pulse 104A, 104B and the length of the fence wire 106A, 106B.

Should one or more parameters of the received power pulse 104A, 104B exceed or fall below a threshold, the energiser 102 may be configured to generate one or more alarms to notify of a fault or potential breach condition on the fence.

For example, if the measured parameter is voltage, then a decrease in the voltage measured at the detector 114 may indicate that a person, animal, vegetation or a short has been applied to one or more wires of the fence, or a cut or break of one or more wires of the fence has occurred.

In examples, the system 100 includes one or more environmental sensors 120 configured to collect data from the surrounding environment. For example, the one or more environmental sensors 120 may be configured to provide environmental data such as temperature, humidity, soil characteristics (for example, conductivity), salinity, solar radiation, wind characteristics (for example, direction and/or velocity), and/or weather characteristics (for example, rain and/or snow). In examples, the system may receive data from external services or data sources 122, for example a weather reporting service.

In examples, the system includes one or more security sensors 124. For example, the security sensors 124 may include one or more of: tension or motion sensors to detect movement of the fence wire; sensors such as cameras, infra-red, microwave or radar to detect movement near the fence; sensors such as an accelerometer attached to the fence structure to detect movement of the fence structure; and fibre or coaxial cables attached to the fence to detect movement of the fence (or buried under ground to detect movement near the fence).

For a firmware and/or software (also known as a computer program) implementation, the techniques of the present disclosure may be implemented as instructions (for example, procedures, functions, and so on) that perform the functions described. It should be appreciated that the present disclosure is not described with reference to any particular programming languages, and that a variety of programming languages could be used to implement the present disclosure. The firmware and/or software codes may be stored in a memory, or embodied in any other processor readable medium, and executed by a processor or processors. The memory may be implemented within the processor or external to the processor.

Control may be performed by a processor, and more particularly a microprocessor: a self-contained computer system capable of storing and executing software instructions, receiving input from peripheral circuitry and providing output signals to peripheral circuitry. The term microprocessor also encompasses field programmable gate arrays FPGA's that have been configured for the same purpose of determining security events. A general purpose processor may be a microprocessor, but in the alternative, the processor may be any suitable processor, controller, microcontroller, or state machine. A processor may also be implemented as a combination of computing devices, for example, a combination of a digital signal processor (DSP) and a microprocessor, a plurality of microprocessors, one or more microprocessors in conjunction with a DSP core, or any other such configuration. In an exemplary embodiment the security system may include storage for recording values of the monitored condition. This storage may comprise volatile memory, such as RAM, or non-volatile memory such as flash memory. In some applications, it may be advantageous that the storage includes both volatile and non-volatile memory, for example as is common in micro-controllers. In an alternative embodiment the storage, may comprise electronic components such as shift-registers.

The steps of a method, process, or algorithm described in connection with the present disclosure may be embodied directly in hardware, in a software module executed by one or more processors, or in a combination of the two. The various steps or acts in a method or process may be performed in the order shown, or may be performed in another order. Additionally, one or more process or method steps may be omitted or one or more process or method steps may be added to the methods and processes. An additional step, block, or action may be added in the beginning, end, or intervening existing elements of the methods and processes.

### 6.2. Parameter Measurement

Traditionally, detection circuits 116 have been based on detecting the peak voltage at the second or distal end of the fence wires 106A, 106B. This can either be done by continuously sampling the power pulse 104A, 104B voltage waveform, using a processor such as a microcontroller or digital signal processor, or by using some form of peak-hold circuit, or wave shape analysis, as should be familiar to those skilled in the art.

When a wire 106A, 106B is cut, the power pulse 104A, 104B does not propagate through to the detection circuit 116A, 116B of the energiser 102. However, it has been observed that an attenuated version of the power pulse 104A, 104B present on the adjacent wires, may be parasitically coupled into the cut fence wire 106A, 106B for example by capacitive or inductive coupling.

This coupled signal is of the opposite polarity to the signal transmitted by the pulse generator 110A, 110B of the cut wire. However, voltage oscillations in the coupled signal may be picked up by the associated detection circuit 116A, 116B and measured by the detector as if they were the intended signal. In particular the voltage overshoot/swing of a return power pulse 204A, 204B is of the opposite polarity to the sent power pulse 202A, 202B and may be of a sufficient voltage to ensure that a low-voltage alarm threshold is not triggered.

### 6.2.1. Improved Measurement Techniques

One approach to improving the power pulse measurement is to sample the power pulse 104A, 104B waveform at a predetermined time after the trigger signal 112 triggers the pulse generating circuits 110A, 110B.

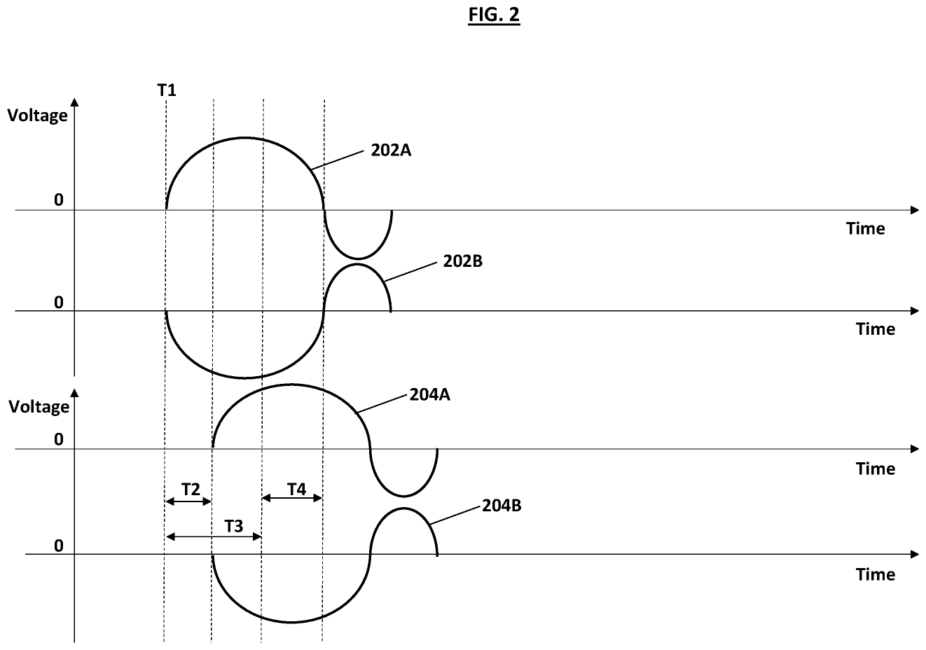

FIG. 2 shows exemplary waveforms which illustrate one method of improving the measurement techniques in accordance with the present technology. As shown two outgoing power pulses 202A, 202B are generated at a time T1 which coincides with the trigger signal 112 generated by the pulse timing circuit 108. Two returning power pulses 204A, 204B are received by the detector circuit after a delay time T2. It should be appreciated that the power pulse waveforms 202A, 202B are representative of the waveform present at the first end of the fence wires 106A, 106B, while the power pulse waveforms 204A, 204B are representative of the waveform present at the distal or second end of the fence wires 106A, 106B.

For the purposes of this example, the power pulses 202A and 202B are supplied to the fence wires simultaneously, however this should not be seen as limiting as previously discussed. Furthermore, the power pulse waveforms are illustrated in a simplified manner with power pulse 202A as a positive power pulse, and power pulse 202B as a negative power pulse. For sake of simplicity these waveforms are shown with a single polarity swing/inversion/overshoot, it should be appreciated that in practice power pulse waveforms are generally more complex and can vary based on fence loading, and environmental conditions such as temperature and humidity.

It should further be appreciated that while the waveforms illustrated in FIG. 2 are voltage waveforms, this should not be seen as limiting on the technology and suitable power pulse parameter may instead be measured such as current, or electric field strength.

In one example of the technology it may be advantageous to delay the sampling of the return power pulse waveforms 204A, 204B for a predetermined delay time after the generation of the power pulse 202A, 202B or trigger signal 112. For example, the delay time may be equal to the expected pulse transmission delay which itself is a function of the length of fence and the propagation velocity of the power pulses 202A, 202B. By delaying the sampling of the return pulse waveforms 204A, 204B, the total amount of sampling and processing may be reduced, improving power efficiency and reducing the likelihood of triggering on false information, such as parasitically coupled signals or static electricity discharges for example. By way of example, the delay time T2 may be approximately 10 microseconds after the generation of the power pulse 202A, 202B or trigger signal 112.

In another example of the technology, it may be advantageous to delay the sampling of the return power pulse waveforms 204A, 204B for a longer delay period T3 so as to better capture the peak of the power pulse waveform 204A, 204B. For example, the delay period T3 may be substantially based on the expected pulse transmission delay in combination with the expected pulse rise time. By way of example, the delay time T3 may be approximately 20 microseconds after the generation of the power pulse 202A, 202B or trigger signal 112.

A yet further improvement to the waveform measurement technique is to limit the duration in which the power pulse is sampled. For example, the measurement of the power pulses 204A, 204B may be delayed by a delay time T3, and measured only for a predetermined duration T4. In this way the detector 114 can be configured to process only the peak of the waveform, and at a time when the waveform peak is expected to occur. By way of example, the duration T4 may be approximately 10 microseconds.

By only processing waveform parameters during a specific time period, the present technology is able to effectively filter out spurious waveform data which may otherwise contribute to false positives or false negatives.

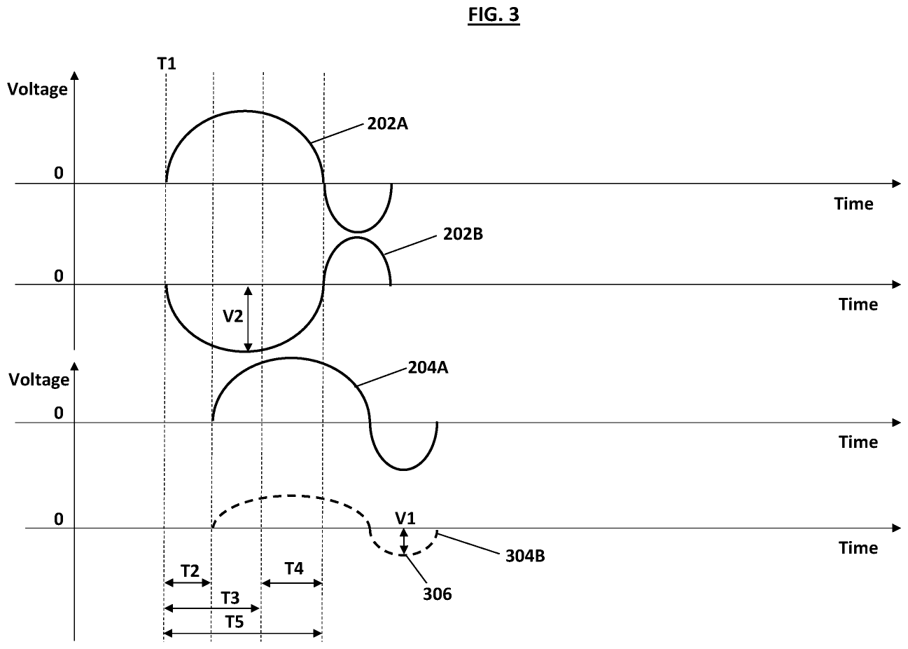

For example, one application of the present technology is to filter out parasitically coupled pulses from adjacent fence wires. As shown in FIG. 3.

FIG. 3 shows two outgoing power pulses 202A, 202B of opposite polarities. Like the previous example, these power pulses 202A, 202B are generated substantially simultaneously by the pulse generating circuits 110A, 110B and are synchronised by a trigger signal 112. The illustrated power pulses 202A and 202B are measured at a first end of the fence wires 106A and 106B proximate to the energiser 102 (or internal to the energiser 102).

Also shown are two incoming pulses 204A and 304B, which are measured at a second or distal end of the fence wires 106A and 106B. However, unlike the example of FIG. 2, this example assumes that the fence wire 106B has been disconnected or cut at some point along its length. Accordingly, the power pulse 304B is not a time offset version of the transmitted pulse 202B, but rather is a parasitically coupled (i.e. capacitively and/or inductively coupled) version of the signal 204A. Accordingly the parasitically coupled waveform has a positive waveform as opposed to the negative waveform which would be expected.

In a single energised fence wire system, there would be no adjacent wires to parasitically couple the power pulse, accordingly, cutting or disconnecting the fence wire would simply remove the return pulse and the detector can detect this and generate an alarm accordingly. However in multi-energiser configurations or where the energiser 102 has multiple pulse generation circuits 110A, 110B a pulse or a portion of a pulse from an adjacent wire may be coupled into the cut wire and the detection system may not be able to discriminate between the expected pulse and a parasitic/cross-coupled pulse from an adjacent wire.

In other words, traditional peak voltage measurement techniques may detect the negative swing 306 of 304B and determine that the signal level received indicates that the integrity of the fence network has been maintained and not generate an alarm. Accordingly, a user may be able to breach the fence network without an alarm being triggered.

By way of example, the detection circuit 116B may be configured to look for a peak negative voltage V1 which is within 50% of the peak negative voltage V2 transmitted to the fence wire. Using the traditional methods of peak detection may cause the negative swing 306 to meet this criterion and a potential alarm condition may be ignored.

The present technology overcomes this limitation by only sampling, or processing the waveform parameters after a predetermined delay and for a predetermined duration as previously discussed. Accordingly, as virtually no peak negative voltage is present during duration T4, the detector is able to assume that the wire has been cut or disconnected and generate an alarm accordingly.

Another advantage of the present technology is that it is able to detect situations where an attacker connects the cut section of wire to one of the other wires on the fence, in an attempt to trick the detection circuits. Accordingly, in these examples, the parasitic waveform 304B is instead replaced by a copy of waveform 204A.

While the foregoing discussion primarily focuses on sampling the incoming power pulse waveforms 204A, 204B after certain delay periods (T2, T3) or for predetermined durations (T4) it should be appreciated that this is not limiting on the scope of the technology. In an alternative implementation of the technology, the detector may be configured to continuously sample the power pulse waveforms 204A, 204B but only process the waveform data which occurs during the desired time window when making decisions as to the peak voltage, current or electromagnetic field strength intensity or the incoming power pulse waveforms 204A, 204B.

It should also be appreciated that any suitable waveform sampling techniques may be used within the scope of the present technology. For example, a peak-hold circuit may be activated or sampled during the desired window. Alternatively, or additionally, waveform samples may be taken at a regular interval such as every 1 microsecond.

### 6.2.2. Pulse Polarity Sequencing

Another advantage of the present technology is the ability to discriminate between expected return pulses and cross-coupled/parasitic pulses or pulses caused by shorted wires by analysing the polarity of or sequence of polarities present in the return pulse.

For example, power pulse 202A in FIG. 3 has a predominantly positive waveform, followed by a negative voltage swing. Accordingly, the expected waveform received at the detector 114 should have a similar positive followed by negative voltage swing. Any variations from this expected return waveform may be configured to generate an alarm accordingly.

These aforementioned polarity sequencing techniques can further be improved by sampling or processing data received after a predetermined delay time and for a predetermined duration as described herein. This approach can advantageously ensure that the correct polarity sequences are compared. Particularly in situations which multiple polarity inversions or “ringing” is present in the power pulse waveforms.

### 6.2.3. Waveform Calibration

In the foregoing examples reference is made to predetermined delays, durations and thresholds. It should be appreciated that these delays durations and thresholds may be pre-programmed, configured on installation or adjusted in real-time using one or more of the techniques described herein.

For example, the predetermined delay time T3 is determined by the amount of time for the power pulse wave to travel from the first end of the fence line to the second end of the fence line. This predetermined delay time T3 may be calibrated when an electric fence system 100 is first installed and commissioned. Generally, security fence lines do not change in length over the lifetime of the installation and if they do the predetermined delay time T3 may be recalibrated to take into account any change in fence length or characteristics.

One method of calibrating the predetermined delay T3 to is to provide a power pulse on one or more of the fence wires and measure the amount of time it takes before detecting the power pulse at the detector on the second end of the fence wire. Thereby measuring the pulse propagation delay T2.

In examples described herein, the predetermined delay time T3 consists of the pulse propagation time T2 plus an amount of time which is a proportion of the power pulse until a sample of the pulse is taken. For example, the proportion of the power pulse may be a portion of the rise time of the power pulse waveform. For example, with reference to FIG. 3 where the main portion of one polarity of the power pulse T5 is 70 microseconds and where the transit time T2 is 20 microseconds, then a predetermined delay time of 40 microseconds may be chosen. This time is calculated from the transit time T2 plus the time to the peak of main portion of the power pulse (20 microseconds plus 25 microseconds) minus a small time (5 microseconds) to take into account small variations in fence characteristics of the particular fence installation being calibrated.

The predetermined duration T4 can then be determined as being a window of time either side of the predicted peak of the voltage waveform. For example, a duration may be 10 microseconds, so that any change in the peak of the waveform due to varying fence line conditions may be detected. For example, prior to a wire being cut the peak measured voltage within the 10 microsecond time window after a 40 microsecond time delay may be 7000 volts whereas after a wire is cut the measured voltage may be 100 volts. In alternative examples, this may be determined as a single instance rather than a time window.

In another example of the technology, waveform pulse shape may be analysed to determine if an expected pulse is being measured by the detection circuit or if it is a cross coupled pulse. The expected pulse shape may be determined by a calibration procedure when the fence and energising system is initially installed or it may be determined by a machine learning algorithm which records and analyses the pulse shape for each expected pulse on the fence over time. Both approaches may be configured to allow for gradual changes in the shape over time (due to slow moving environmental factors), either by defining limits for the expected pulse shape, or by gradually updating the expected pulse shape to account for the gradual chances. In this way false alarms can be reduced and only sudden changes due to an intruder event or sudden change in the fence condition will trigger an alarm.

In an alternative embodiment a machine learning system may be used to analyse power pulse waveforms present on multiple fence wires energised by multiple pulse generating circuits. The machine learning system can be used to compare the changing pulse parameters on one fence wire with the changes in pulse parameter on all the fence wires to determine whether a change on the pulse parameter in question is due to an environmental effect occurring on all the fence wires or an intruder event occurring on the wire in question. For example, in a heavy rain shower the pulse voltage on all the fence wires may drop by 40% over a short period of time and so a change of 40% in voltage on any particular fence wire would not indicate an intruder event, rather an environmental effect occurring on all the fences. This embodiment may result in less false alarms where the combined data from all the pulses on all the fences is used to discriminate the effects of environment from an intruder attack on a particular fence line.

In embodiments, one or more machine learning algorithms may be used to analyse the at least one parameter of the power pulse in combination with data from the one or more sensors 120 or 124 to determine a relationship between environmental effects and the power pulse voltage or waveform shape. In doing so the system can assign a probability to the cause of a change in the power pulse voltage or waveform, for example external environmental factors, or the result of an intruder attack on the fence. The machine learned probability assigned to the cause of the change in voltage or waveform shape can be used for determining whether to report the change as an intruder event that needs to be further investigated or an environmental related event that does not need to be further investigated and would otherwise be reported as a false alarm event. In doing so, the likelihood of false alarms may be reduced, and/or sensitivity to genuine alarms or intruder events increased.

For example, in known security electric fence monitoring systems the threshold to trigger an alarm event may be set at an absolute value such as 3000 volts. Under normal operation the output voltage may be at 7000 volts, and when the voltage measured on the fence drops below 3000 volts an alarm is triggered. However, when environmental conditions such as heavy rain or contaminated insulators cause the voltage to fall to 2900 volts an alarm event may be triggered but it will not be due to an intruder event—i.e. the alarm event will be a false alarm. By using machine learning, rather than an absolute value, a threshold may be set e.g. as a percentage of the recent value or accumulated average values of recent voltage measurements. For example, while the measured voltage on the fence is 7000 volts the alarm threshold may be adaptively set to 6300 volts. When the measured voltage has moved over a time period to 3000 volts due to environmental factors, then the alarm threshold may be adaptively set to 2700 volts. So the alarm threshold is more sensitive to intruder events but less sensitive to causing false alarms. Furthermore, when data from other sensors such as humidity sensors are also analysed together with changing voltages on the fence a more accurate determination of the cause of voltage variation can be made to discriminate between environmental induced voltage changes and intruder event induced voltage changes.

### 6.2.4. Other Examples of the Technology

The foregoing examples have primarily focused on including a detector within an energiser 102, however this should not be seen as limiting on the scope of the technology and in other examples of the technology the detector may be a device which is located remotely from the energiser 102.

### 6.3. DISCLAIMER

All references, including any patents or patent applications cited in this specification are hereby incorporated by reference. No admission is made that any reference constitutes prior art. The discussion of the references states what their authors assert, and the applicants reserve the right to challenge the accuracy and pertinency of the cited documents. It will be clearly understood that, although a number of prior art publications are referred to herein, this reference does not constitute an admission that any of these documents form part of the common general knowledge in the art, in New Zealand or in any other country.

Throughout this specification, the words “comprise” and “include”, or variations thereof such as “comprises” or “comprising”, or “includes” or “including”, will be understood to imply the inclusion of a stated element, integer or step, or group of elements integers or steps, but not the exclusion of any other element, integer or step, or group of elements, integers or steps.

The foregoing technology may be said broadly to consist in the parts, elements and features referred to or indicated in the specification of the application, individually or collectively, in any or all combinations of two or more of said parts, elements or features.

Aspects of the present technology have been described by way of example only and it should be appreciated that modifications and additions may be made thereto without departing from the scope thereof.

1. A system for monitoring an electric fence, the system comprising:
an electric fence energiser, comprising:
a power source;
a power pulse generating circuit; and
a power pulse triggering circuit adapted to provide a trigger signal to the power pulse generating circuit, and
a detector, comprising detection circuitry configured to measure at least one parameter of a power pulse,
wherein, in use the electric fence energiser is electrically connected to a first end of the electric fence, and the detector is electrically connected to a second end of the electric fence, and
wherein, the power pulse generating circuit is configured to transmit a power pulse to the electric fence upon receiving the trigger signal, and the detector is configured to measure the at least one parameter of the power pulse at a predetermined delay time after the trigger pulse is provided to the power pulse generating circuit.

2. The system of claim 1, wherein the detector is configured to generate an alarm when the at least one parameter falls outside of at least one threshold.

3. The system of claim 2, wherein the at least one threshold is configured during installation.

4. The system of claim 2, wherein the at least one threshold is adjusted over time.

5. The system of claim 4, wherein the at least one threshold is adjusted based at least in part on sensed environmental effects on the fence.

6. The system of claim 1, wherein the electric fence comprises two or more electric fence zones, wherein each electric fence zone includes a first and a second electric fence line, the first electric fence line being adjacent to and spaced apart from the second electric fence line;
wherein, in use, the electric fence energiser is electrically connected to a first end of the first electric fence line and a first end of the second electric fence line; and
wherein, in use, the detector is electrically connected to a second end of the first electric fence line and a second end of the second electric fence line,
wherein in use, the electric fence energiser supplies the first electric fence line with an electric pulse beginning with a positive polarity and the second electric fence line with an electric pulse beginning with a negative polarity, and
wherein the detector is configured to monitor one or more parameters of the electric pulse on the first electric fence line and/or one or more parameter of the electric pulse on the second electric fence line, and generate an alarm when the one or more parameters fall outside of one or more thresholds, the one or more thresholds being based at least partially upon measured parameters of the other fence zones over time.

7. The system of claim 1, wherein the electric fence energiser is configured to communicate timing information of the power pulse triggering circuit to the detector.

8. The system of claim 1, wherein the power pulse triggering circuit is configured to provide power pulses at a regular interval.

9. The system of claim 1, wherein the power pulse triggering circuit is configured to synchronise the generation of power pulses with the generation of power pulses on neighbouring sections of fence or generated by other energiser units.

10. The system of claim 1, wherein the at least one parameter comprises one or more of: voltage, current or electromagnetic field.

11. The system of claim 1, wherein the detector is configured to repeatedly or continuously measure the at least one parameter of the power pulse for a predetermined duration after the predetermined delay time.

12. The system of claim 11, wherein the predetermined duration is based on the expected width of the power pulse.

13. The system of claim 11, wherein the predetermined duration is determined by comparing the shape of the generated pulse to the shape of the returning pulse at the detector.

14. The system of claim 1, wherein the predetermined delay time is based on the propagation time of a power pulse on the fence.

15. The system of claim 14, wherein the predetermined delay time is based on both the propagation time, and the expected rise time of the power pulse waveform.

16. The system of claim 1, wherein the predetermined delay time is calibrated during installation of the fence system.

17. The system of claim 1, wherein the predetermined delay time is adjusted over time.

18. The system of claim 1, wherein the electric fence energiser is configured to measure the at least one parameter of the power pulse at the time of generating the power pulse.

19. The system of claim 18, wherein the at least one parameter measured by the energiser is compared with the at least one parameter measured by the detector.

20. A method of monitoring a fence system, the method comprising the steps of:
supplying at least one power impulse to the fence system;
measuring at least one parameter of the power impulse on the fence system, a predetermined delay time after the impulse was supplied to the fence system;
continuing to measure the at least one parameter of the power impulse for a predetermined duration after the predetermined delay time has expired; and
generating one or more alarms if the measured parameter falls outside of at least one threshold.
